(19) United States
(12) Patent Application Publication
(10) Pub. No.: US 2024/0147875 A1
(43) Pub. Date: May 2, 2024

(54) PHASE CHANGE RAM DEVICE AND METHOD FOR FABRICATING THE SAME

(71) Applicant: Korea Advanced Institute of Science and Technology, Daejeon (KR)

(72) Inventors: Shinhyun CHOI, Daejeon (KR); See-On PARK, Daejeon (KR); Seok Man HONG, Daejeon (KR)

(73) Assignee: Korea Advanced Institute of Science and Technology, Daejeon (KR)

(21) Appl. No.: 18/489,172

(22) Filed: Oct. 18, 2023

(30) Foreign Application Priority Data
Oct. 31, 2022 (KR) 10-2022-0142950
Jan. 17, 2023 (KR) 10-2023-0006942

(51) Int. Cl. H10N 70/00; H10B 63/10; H10N 70/20

(52) U.S. Cl. CPC H10N 70/828; H10B 63/10; H10N 70/011; H10N 70/231

(57) ABSTRACT

Provided is a phase change RAM. The phase change RAM includes an electrode, a first layer located on the electrode, and a second layer located on the first layer. The first layer includes a locally formed phase change material region. In addition, a method of manufacturing a phase change RAM is provided. The method includes forming an electrode, forming a first layer on the electrode, forming a second layer on the first layer, and forming a phase change material region locally in the first layer due to a voltage applied to the second layer.

### CROSS-REFERENCE TO RELATED APPLICATIONS

This application claims priority to Korean Patent Application No. 10-2023-0006942 filed on Jan. 17, 2023 and Korean Patent Application No. 10-2022-0142950 filed on Oct. 31, 2022, the entire contents of which are herein incorporated by reference.

### BACKGROUND

### 1. Field

One or more embodiments relate to a phase change RAM (PRAM or PCRAM) device and a method of manufacturing the same. More particularly, one or more embodiments relate to a phase change RAM cell structure using a phase change material region created by combining respective materials of at least two layers located on an electrode, a phase change RAM (PRAM or PCRAM) device using the phase change RAM cell structure, and a method of manufacturing the phase change RAM device.

### 2. Description of the Related Art

A phase change RAM device is a memory device that uses a change in the phase of a specific material. In other words, when a specific material changes into an amorphous state or a polycrystalline state, a change in resistance occurs, and the change in resistance has a meaning as data of a memory. At this time, a change in the phase of the material is determined by temperature and time.

In other words, when the material is heated for a certain period of time between a crystallization temperature, which is a relatively low temperature, and a melting point and then slowly cooled, the material is crystallized. At this time, the crystallized material maintains a low resistance state, which is a state in which data ‘0’ is stored. In addition, when the material is heated to a temperature above the melting point and then rapidly cooled, the material becomes amorphous. At this time, the amorphous material maintains a high resistance state, which is a state in which data ‘1’ is stored.

In such an operating mechanism of a phase change RAM, a set state that induces a crystallization state is performed at a relatively low temperature, and accordingly does not require a large amount of current. However, a reset state that induces an amorphous state requires a high amount of current. Therefore, in order to manufacture a memory device with high integration, efforts are needed to reduce the amount of current for reset during a reset operation.

### SUMMARY

One or more embodiments include a phase change RAM device that requires a low reset current of 60 μA or less by using a phase change material region created by combining materials that respectively constitute material layers, and a method of manufacturing the phase change RAM device.

One or more embodiments include a phase change RAM device that does not require an expensive process for nanometer (nm)-level patterns by eliminating the structure of a bottom electrode contact (BEC) and may be manufactured at low process costs regardless of pattern sizes, and a method of manufacturing the phase change RAM device.

One or more embodiments include a phase change RAM device capable of achieving low power consumption through a low operating current without a BEC by forming a nanoscale filament-shaped phase change material region within the phase change RAM device by combining respective materials of two material layers with each other, and a method of manufacturing the phase change RAM device.

One or more embodiments include a phase change RAM device that is simple, compared with an existing PRAM manufacturing process, does not require an expensive process such as E-beam lithography or ArF immersion, and conforms to a current semiconductor process by using a material compatible with an existing semiconductor, and a method of manufacturing the phase change RAM device.

The technical problems of the present invention are not limited to the above-mentioned contents, and other technical problems not mentioned will be clearly understood by a person skilled in the art from the following description.

According to an embodiment of the disclosure, a phase change RAM includes an electrode, a first layer located on the electrode, and a second layer located on the first layer, wherein the first layer includes a locally formed phase change material region.

The phase change RAM may further include a top electrode located on the second layer.

The phase change material region may comprise a combination of a material of the first layer and a material of the second layer.

The material of the first layer may include silicon (Si), and the material of the second layer may include tellurium (Te).

The material of the first layer may include a Group 14 element, and the material of the second layer may include a Group 15 or 16 element.

The second layer may function as a top electrode.

The phase change material region may have a nanoscale filament shape.

The phase change material region may be formed by providing the material of the second layer to the first layer due to a voltage applied to the second layer.

According to another embodiment of the disclosure, a phase change RAM includes an electrode, a first layer located on the electrode, and a second layer located on the first layer, wherein the first layer includes a locally formed nanofilament, and the nanofilament has phase change material characteristics.

According to another embodiment of the disclosure, a method of manufacturing a phase change RAM includes forming an electrode, forming a first layer on the electrode, forming a second layer on the first layer, and forming a phase change material region locally in the first layer due to a voltage applied to the second layer.

### BRIEF DESCRIPTION OF THE DRAWINGS

FIG. 1 is a view for describing a conventional phase change RAM (PRAM) structure.

FIGS. 2A and 2B are views for explaining a structure, a manufacturing method, and an operating principle of a PRAM, according to an embodiment of the disclosure.

FIG. 3 is an exemplary view for describing a structure and an operation principle of a PRAM according to an embodiment of the disclosure.

FIG. 4 is a graph showing experimental results showing a reset current of a PRAM device according to an embodiment of the disclosure.

### DETAILED DESCRIPTION

The disclosure will now be described more fully with reference to the accompanying drawings, in which exemplary embodiments of the disclosure are shown. The disclosure may, however, be embodied in many different forms and should not be construed as being limited to the embodiments set forth herein.

The terminology used herein is for the purpose of describing particular embodiments only and is not intended to limit the disclosure. As used herein, the singular forms “a”, “an” and “the” are intended to include the plural forms as well, unless the context clearly indicates otherwise.

It will be understood that the terms “comprises” and/or “comprising,” when used in this specification, specify the presence of stated components, steps, operations, and/or elements thereof, but do not preclude the presence or addition of one or more other components, steps, operations, and/or elements thereof.

In the description, certain detailed explanations of the related art are omitted when it is deemed that they may unnecessarily obscure the essence of the disclosure.

Hereinafter, the disclosure will be described more fully with reference to the accompanying drawings, in which exemplary embodiments of the disclosure are shown. The configuration of the disclosure and the effect of the action thereof will be clearly understood through the following detailed description.

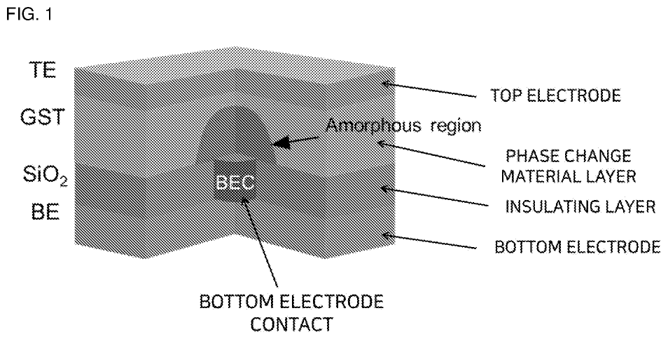

FIG. 1 is a view for describing a conventional phase change RAM (PRAM) structure.

In general, when a current is applied through a bottom electrode in a PRAM device, the temperature of a phase change material layer changes due to the Joule heat generated due to the application of the current, and the crystal structure of the phase change material layer may be changed to a crystalline state or an amorphous state by appropriately changing the applied current. In other words, a phase change occurs between a crystalline state with low resistance (SET state) and an amorphous state with high resistance (RESET state) due to Joule heat, and a current flowing through a phase change layer may be detected in write and read modes to determine whether the information stored in a phase change memory cell is data 0 in a set state or data 1 in a reset state.

Referring to FIG. 1, there is a phase change material layer composed of a phase change material below a top electrode TE, and a chalcogen compound, such as Ge—Sb—Te (GST), may be representatively used as the phase change material. According to a conventional structure as shown in FIG. 1, the size of a bottom electrode BE, which acts as a heater for heating the phase change material, such as GST, is very important in a PRAM device, and the amount of current generated in a reset process among set/reset processes of PRAM determines the lifetime of the PRAM device, a sensing margin, and shrinkage of the PRAM device.

However, in this conventional structure, a current is injected through a small electrode of a confined electrode such as a BEC, and reset is performed using the heat generated due to the current injection, and, because an electrode size needs to be extremely small in order to generate high heat, a fine pattern of 40 nm or less needs to be formed. To this end, an expensive process such as E-beam lithography or ArF immersion is needed, resulting in enormous process costs. In addition, such a conventional PRAM structure must use a high reset current of several hundreds of microamperes (μA) or more according to the characteristics of melting the inside by flowing a reset current.

This remains a demand for a new PRAM structure capable of reducing process costs compared to a conventional structure by having a low reset current without forming an electrode structure such as a conventional BEC.

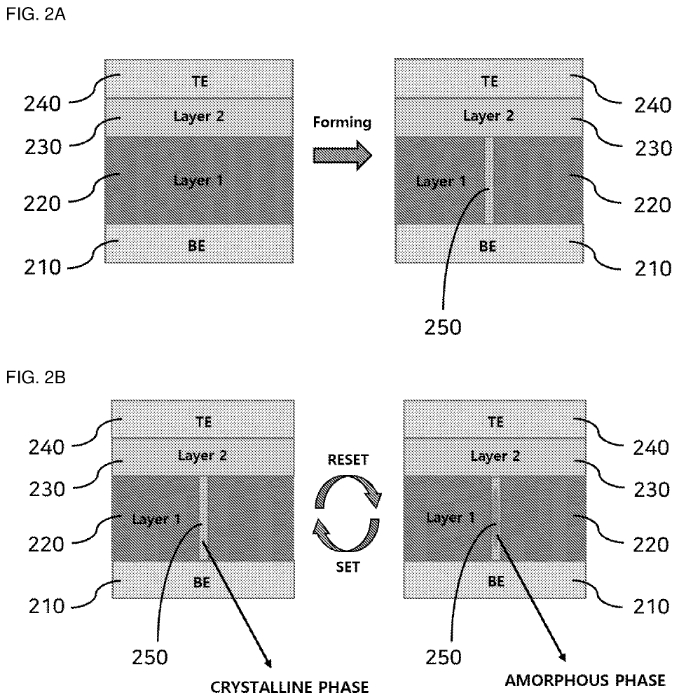

FIGS. 2A and 2B are views for explaining a structure, a manufacturing method, and an operating principle of a PRAM, according to an embodiment of the disclosure.

Referring to FIG. 2A, a phase change RAM device structure may include a bottom electrode 210, a first layer 220 located on the bottom electrode 210, a second layer 230 located on the first layer 220, and a top electrode 240 located on the second layer 230. For example, the second layer 230 may function as a top electrode without the presence of the top electrode 240 disposed on the second layer 230.

A method of manufacturing such a phase change RAM device may include forming the bottom electrode 210, forming the first layer 220 on the bottom electrode 210, forming the second layer 230 on the first layer 220, forming the top electrode 240 on the second layer 230 (this operation may be omitted), and forming a phase change material region 250 locally on the first layer 220 due to a voltage applied to the top electrode 240 or the second layer 230.

When a large voltage of 5 to 10 V, for example, is applied to the second layer 230 through the top electrode 240 or the second layer 230, a material constituting the second layer 230 descends to the first layer 220 by an electric field and provided to the first layer 220, and thus the phase change material region 250 may be formed locally in the first layer 220, and may be composed of a combination of the material of the first layer 220 and the material of the second layer 230. In other words, the material of the second layer 230 penetrates into the first layer 220 due to application of a voltage to form the phase change material region 250 as a local combination region, and the phase change material region 250 formed in this way changes in crystal phase without changing in shape and may operate to have phase change material characteristics.

The phase change material region 250 has a shape of a nanoscale filament. Because the filament formed in this way has phase change characteristics and a very thin nanoscale filament is naturally formed, the phase change material region 250 may operate even with a very low current.

For example, the material of the second layer 230 may be composed of tellurium (Te), the material of the first layer 220 may be composed of silicon (Si), and, due to this selection and combination of the materials of the two layers, a nanofilament formed in the phase change material region 250 may have phase change material characteristics. The material of the second layer 230 may be, for example, any one of a Group 15 element such as P, As, or Sb, or a Group 16 element including a chalcogen element such as Te, S, or Se, or a combination thereof, and the material of the first layer 220 may be, for example, any one of a Group 14 element, such as Si or Ge, or a combination thereof and also may be a material with low thermal conductivity. In this case, because the thermal conductivity of the first layer 220 or the second layer 230 in which the phase change material region 250 is formed is lower than that of general metals, no additional process to prevent heat conduction is needed.

Referring to FIG. 2B, the nanofilament formed in the phase change material region 250 has phase change material characteristics between a crystalline state (SET state) with low resistance and an amorphous state (RESET state) with high resistance for an operation of the PRAM device according to an embodiment of the disclosure, and, unlike a conventional structure, the PRAM device according to an embodiment of the disclosure does not need a special electrode such as a BEC, and is able to operate with a very low reset current regardless of device sizes.

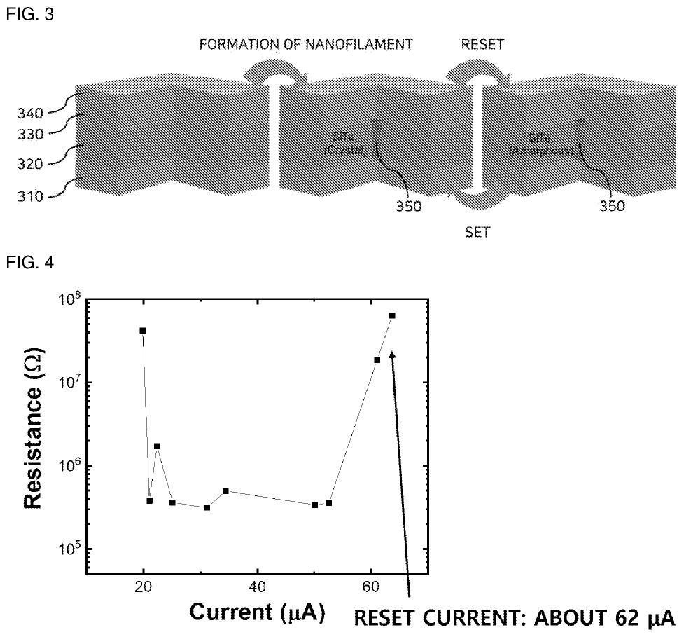

FIG. 3 is an exemplary view for describing a structure and an operation principle of a PRAM according to an embodiment of the disclosure.

FIG. 3 illustrates an example of the structure of FIGS. 2A and 2B, and the structure of FIG. 3 includes a bottom electrode 310, a first layer 320 composed of Si located on the bottom electrode 310, a second layer 330 composed of Te located on the first layer 320, and a top electrode 340 located on the second layer 330.

A nanofilament 350 may be formed in a phase change material region formed locally in the first layer 320, as a combination of the material of the first layer 320 and the material of the second layer 330, for example, in the form of a chalcogenide compound, such as a SiTeₓ compound.

First, a voltage is applied to the second layer 330 to locally form the thin nanofilament 350 in the first layer 320, and then the nanofilament 359 may operate as a phase change RAM device by having phase change material characteristics between a crystalline state (SET state) and an amorphous state (RESET state).

FIG. 4 is a graph showing experimental results showing a reset current of a PRAM device according to an embodiment of the disclosure.

As a result of testing the PRAM structure of FIG. 3 with a device size of 5×5 μm² in units of micrometers (μm), a low reset current of 62 μA was obtained as shown in FIG. 4. Usually, the structure of a conventional PCRAM device with a device size in the μm unit needs a reset current of 10 A or more. However, a structure according to the disclosure is able to operate with a reset current of a 60 μA level, which corresponds to an operating current approximately 200 times lower than that of a conventional PRAM structure having a 50 nm-sized BEC.

In addition, according to a conventional PRAM structure, such device characteristics have similar operating characteristics to PRAM having a BEC of about 7 to 8 nm. However, according to a memory device structure according to the disclosure, a phase change RAM device that does not require an expensive process, such as E-beam lithography or ArF immersion, and conforms to a current semiconductor process by using a material or the like compatible with an existing semiconductor may be manufactured. Thus, compared to a conventional structure or method, manufacturing costs and process complexity may be dramatically reduced.

According to the disclosure, provided are a phase change RAM device that requires a low reset current of 60 μA or less by using a phase change material region created by combining materials that respectively constitute material layers, and a method of manufacturing the phase change RAM device.

According to the disclosure, provided are a phase change RAM device that does not require an expensive process for nm-level patterns by eliminating the structure of a bottom electrode contact (BEC) and may be manufactured with a low reset current and at low process costs regardless of pattern sizes, and a method of manufacturing the phase change RAM device.

According to the disclosure, provided are a phase change RAM device capable of achieving low power consumption through a low operating current without a BEC by forming a nanoscale filament-shaped phase change material region within the phase change RAM device by combining respective materials of two material layers with each other, and a method of manufacturing the phase change RAM device.

According to the disclosure, provided are a phase change RAM device that is simple compared with an existing PRAM manufacturing process, does not require an expensive process such as E-beam lithography or ArF immersion, and conforms to a current semiconductor process by using a material or the like compatible with an existing semiconductor, and a method of manufacturing the phase change RAM device.

The effects of the disclosure are not limited to the above-mentioned contents, and other effects not mentioned will be clearly understood by a person skilled in the art from the following description.

The above-disclosed embodiments of the disclosure are merely examples, and thus the disclosure is not limited thereto. The scope of the disclosure should be interpreted by the following claims, and all technologies within the scope equivalent thereto should be interpreted as being included in the scope of the disclosure.

What is claimed is:

1. A phase change RAM comprising:
an electrode;
a first layer located on the electrode; and
a second layer located on the first layer,
wherein the first layer includes a locally formed phase change material region.

2. The phase change RAM of claim 1, further comprising a top electrode located on the second layer.

3. The phase change RAM of claim 1, wherein the phase change material region comprises a combination of a material of the first layer and a material of the second layer.

4. The phase change RAM of claim 1, wherein a material of the first layer includes silicon (Si) and a material of the second layer includes tellurium (Te).

5. The phase change RAM of claim 1, wherein a material of the first layer includes a Group 14 element and a material of the second layer includes a Group 15 or 16 element.

6. The phase change RAM of claim 1, wherein the second layer functions as a top electrode.

7. The phase change RAM of claim 1, wherein the phase change material region has a nanoscale filament shape.

8. The phase change RAM of claim 1, wherein the phase change material region is formed by providing a material of the second layer to the first layer due to a voltage applied to the second layer.

9. A phase change RAM comprising:
an electrode;
a first layer located on the electrode; and
a second layer located on the first layer,
wherein the first layer includes a locally formed nanofilament, and the nanofilament has phase change material characteristics.

10. A method of manufacturing a phase change RAM, the method comprising:
forming an electrode;
forming a first layer on the electrode;
forming a second layer on the first layer; and
forming a phase change material region locally in the first layer due to a voltage applied to the second layer.
